(19) United States
(12) Patent Application Publication
(10) Pub. No.: US 2018/0120601 A1
(43) Pub. Date: May 3, 2018

(54) OPTIMIZATION METHOD OF THICKNESS UNIFORMITY OF ALIGNMENT FILM AND LIQUID CRYSTAL DISPLAY PANEL

(71) Applicant: Shenzhen China Star Optoelectronics Technology Co., Ltd., Shenzhen (CN)

(72) Inventors: Ting DOU, Shenzhen (CN); Qiang LI, Shenzhen (CN)

(73) Assignee: Shenzhen China Star Optoelectronics Technology Co., Ltd., Shenzhen (CN)

(21) Appl. No.: 15/128,968

(22) PCT Filed: Jul. 12, 2016
(86) PCT No.: PCT/CN2016/089745

§ 371 Date: Sep. 24, 2016

(30) Foreign Application Priority Data
Feb. 18, 2016 (CN) 201610091187.X

(51) Int. Cl. G02F 1/1337; G02F 1/1368; H01L 27/12; G03F 1/32; G03F 7/16; G03F 7/20; G03F 7/26

(52) U.S. Cl. CPC G02F 1/1337; G02F 1/1368; H01L 27/1288; H01L 27/1296; G02F 2001/13625; G03F 7/16; G03F 7/20; G03F 7/26; G03F 1/32

(57) ABSTRACT

There provides an optimization method of thickness uniformity of alignment film, and the optimization method includes: providing a thin film transistor (TFT) array substrate on which a passivation layer is deposited; coating a photoresist on the passivation layer; dividing the TFT array substrate into different regions, and exposing, developing and etching the photoresist in different regions by respectively using a half tone mask and a common mask; removing the photoresists and depositing an ITO film after etching; etching the ITO film to obtain the TFT array substrate in which upper surfaces of the ITO film and the passivation layer are at a same level; and coating an alignment film on the upper surfaces of the ITO film and the passivation layer. Since the upper surfaces of the ITO film and the passivation layer are at the same level, the thickness of the alignment film coated thereon is uniform.

### BACKGROUND OF THE INVENTION

### 1. Field of the Disclosure

The present invention relates to liquid crystal display technical field, in particular to an optimization method of thickness uniformity of an alignment film and a liquid crystal display panel obtained using the optimization method.

### 2. Description of the Prior Art

With development of touch control and display technologies, the touch control display panel has been widely used in a smart phone, a flat computer and other intelligent electronic products to bring more convenient experience for man-machine interaction.

In general, a main structure of the liquid crystal display panel includes a color filter (CF) substrate, a thin film transistor (TFT) array substrate, a liquid crystal layer and photo spacers (PS) disposed between the CF and TFT substrates, and a sealant frame. On a lower surface of the CF substrate and an upper surface of the array substrate are coated with a polyimide (PI) alignment film, which servers to arrange liquid crystal molecules in a certain direction and angle. Thus, the alignment film is indispensable for the liquid crystal display panel, and the uniformity of its thickness may have a certain impact on optical quality of the liquid crystal display panel.

As shown in FIG. 1, a transparent ITO film 500 used for controlling liquid crystal molecules in a liquid crystal cell to generate a deflection is provided on a passivation layer 100 at a side of a TFT array substrate 2. It can be seen from FIG. 2 that the ITO film has a patterned shape obtained by an etching process, rather than an entire layer deposited on the passivation layer, such that the same ITO films 500 shown in FIG. 1 are not spread continuously, but they are set at a certain interval. Thus, when coating an alignment film 600 on a whole surface of the TFT array substrate 2, part of the alignment film covers on the ITO film, and part of the alignment film covers on the passivation layer 100 at a space corresponding to the interval of the ITO films, which results in thickness difference of the alignment film.

As shown in FIG. 3, a thickness of the alignment film 600 coated on a non-ITO film area (i.e., on the passivation layer 100) is H1, and a thickness of the alignment film 600 coated on the ITO film 500 is H2, thus a difference therebetween can be represented as ΔH=H1−H2. The difference can be referred to as a mismatch of thickness of the alignment film (that is, a difference between a thickness of the alignment film coated on an ITO film and a thickness of the alignment film coated on a non-ITO film area). The mismatch of the alignment film is mainly generated due to the thickness of the ITO film since the thickness of the ITO film results in the alignment film having different thicknesses in different regions. In FIGS. 4(a)-1 to (a)-3, the thicknesses of the ITO film in order are 500 Å, 1000 Å and 2000 Å. FIGS. 4(b)-1 to b-(3) show diagrams of the generation of mismatches after the ITO film is coated with the alignment film. By comparing the above figures, it can be seen that the larger the thickness of the ITO film is, the larger the mismatch ΔH of the alignment film is. In consideration of the function of the alignment film in the liquid crystal display panel, thickness uniformity of the alignment film has an important influence over the display effect of the liquid crystal display panel, thus there is a real need to make an improvement and an optimization to the related technology to solve the above defects on thickness difference and mismatch of alignment film in the above structure.

### SUMMARY

To eliminate defects of the prior art, an object of the present invention is to provide an optimization method of thickness uniformity of an alignment film which is used to a liquid crystal display panel, and the optimization method includes: providing a thin film transistor (TFT) array substrate on which a passivation layer is deposited; coating photoresist on the passivation layer; dividing the TFT array substrate into different regions, and exposing the photoresist in different regions by respectively using a half tone mask and a common mask; developing the photoresist after being exposed using the half tone mask and the common mask; etching the developed photoresist and the passivation layer; removing the photoresist after etching; depositing an ITO film after removing the photoresist; etching the ITO film to obtain the TFT array substrate in which upper surfaces of the ITO film and the passivation layer are at a same level; and coating an alignment film on the upper surfaces of the ITO film and the passivation layer.

As an embodiment, in the optimization method of the present invention, the TFT array substrate is divided into different regions, to respectively perform a half tone mask exposure and a common mask exposure to the photoresists in different regions is to divide the TFT array substrate into a first region and a second region, so as to expose the photoresist in the first region using the half tone mask, and to expose the photoresists in the second region using the common mask. Further, the half tone mask exposure to the photoresist in the first region is an incomplete exposure to the photoresist in the first region using the half tone mask, and an ITO film may be formed in the first region accordingly. The common mask exposure to the photoresist in the second region is a complete exposure to the photoresist in the second region using the common mask, and contact holes may be formed in the second region accordingly. As an embodiment, in the optimization method of the present invention, the photoresist is developed after the half tone mask exposure and the common mask exposure such that the photoresists in the first region form several grooves arranged at intervals and in the second region form openings passing through the photoresists.

Further, the etching to the developed photoresist and the passivation layer is to etch the photoresist in the first region and the passivation layer below the photoresist such that the passivation layer in the first region forms several grooves arranged at intervals, and to etch the passivation layer in the second region to form contact holes passing through the passivation layer in the second region.

Further, the removal of the photoresist after etching is to remove all the photoresists on the passivation layer by using an organic solution.

Further, the deposition of the ITO film after removal of the photoresist is to form the ITO film on the upper surface of the passivation layer by depositing.

As an embodiment, in the optimization method of the present invention, the TFT array substrate in which the upper surfaces of the ITO film and the passivation layer in the first region are in the same level, can be obtained by etching the ITO film.

Further, the alignment film is coated on the whole upper surfaces of the ITO film and the passivation layer, and thus an upper surface of the alignment film is a flat surface.

Further, a lower surface of the alignment film in the first region is a flat surface.

Preferably, the material of the passivation layer is SiNₓ.

A liquid crystal display panel obtained by using the above optimization process includes a CF substrate and a TFT array substrate disposed facing to each other, and a liquid crystal layer disposed between the CF substrate and the TFT array substrate. A passivation layer and an ITO film are provided on the upper surface of the TFT array substrate sequentially, and the upper surfaces of the passivation layer and the ITO film are at the same level and are coated with an alignment film.

Compared with the prior art, the advantages of the present disclosure include:

In the present invention, by employing the half tone mask process, the effect that the upper surfaces of the ITO film and the passivation layer are at the same level can be achieved, so that the alignment film, which is coated on the whole upper surfaces of the ITO film and the passivation layer, has the same thickness and has a good uniformity, and thus it would not cause a mismatch of thickness of the alignment film due to the mismatch between the ITO film and the passivation layer. Moreover, the optimization method in the present invention does not add other manufacturing processes, and it enables the thickness uniformity of the alignment film to be optimized while the process is not complicated, thereby contributing to enhancing display quality of the liquid crystal display panel.

### BRIEF DESCRIPTION OF THE DRAWINGS

FIG. 1 is a section structural diagram of a liquid crystal display panel in the prior art.

FIG. 2 is a distribution diagram of ITO film disposed at a side of the TFT array substrate in the prior art.

FIG. 3 is a detail view of part A in FIG. 1.

FIGS. 4(a)-1 to (a)-3 are diagrams of ITO film with different thicknesses disposed on the passivation layer in the prior art.

FIGS. 4(b)-1 to (b)-3 are diagrams of mismatches generated for coating the alignment film on the ITO films with different thicknesses as shown in FIGS. 4(a)-1 and 4(a)-3.

FIGS. 5-13 are flowcharts of optimization process of thickness uniformity of the alignment film according to embodiment 1 of the present invention.

FIG. 14 is a structural diagram of a liquid crystal display panel according to embodiment 2 of the present invention.

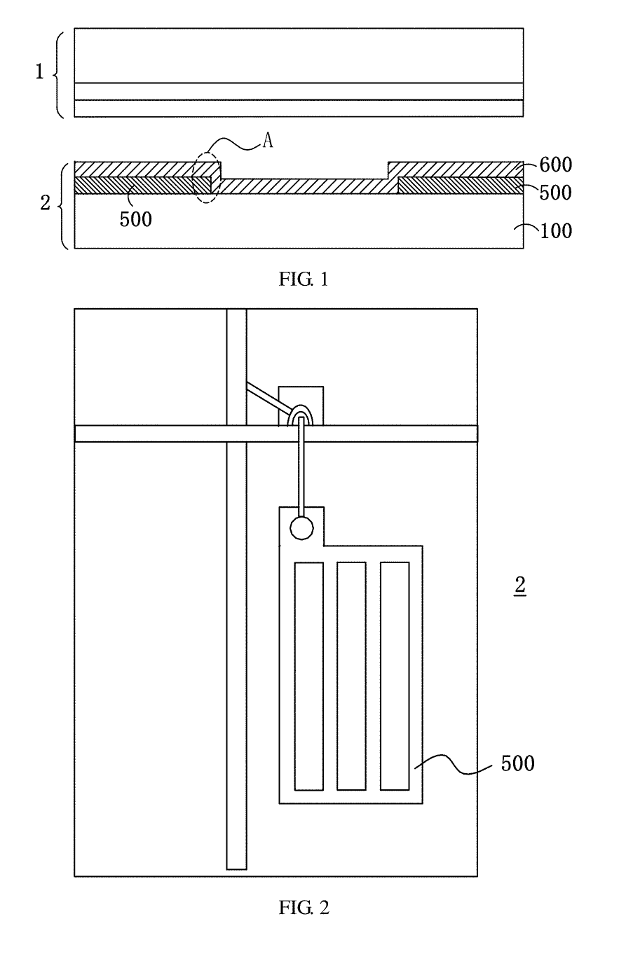

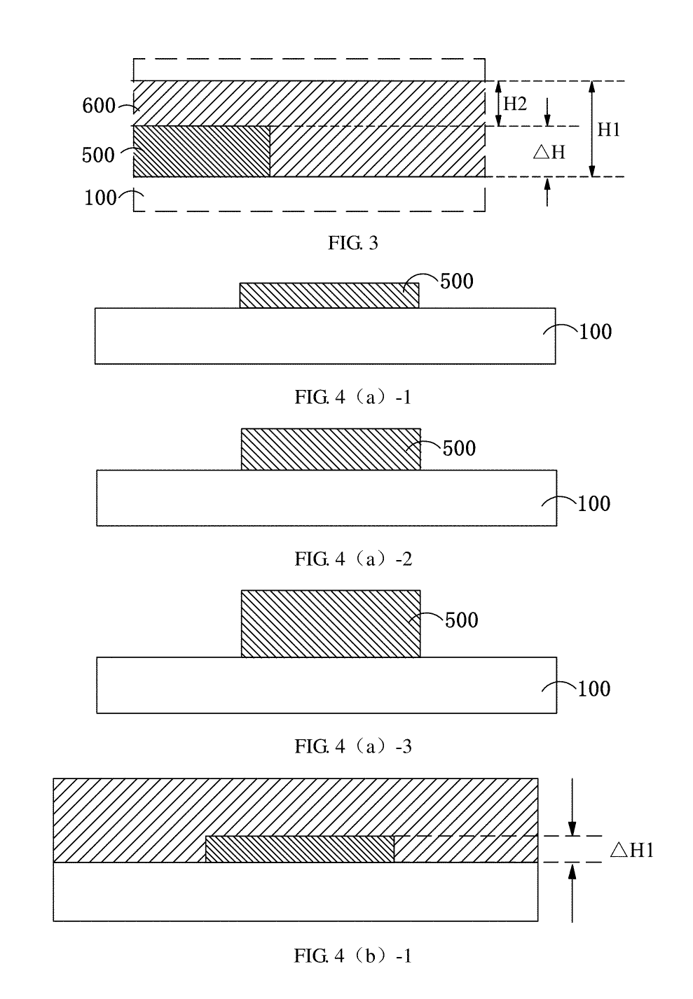

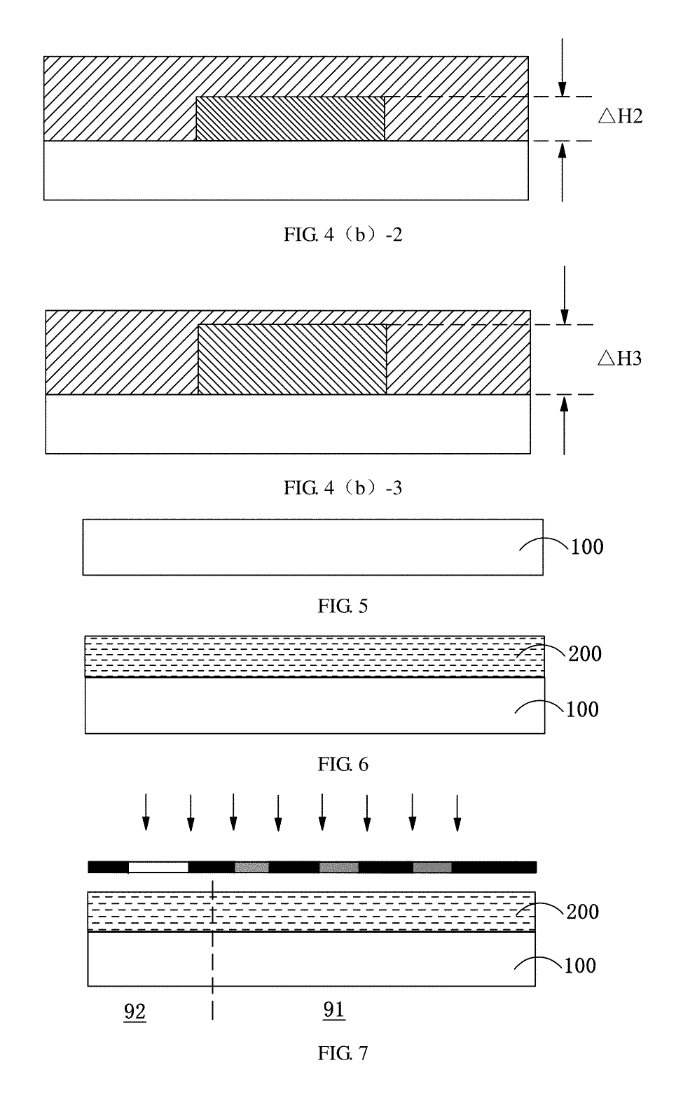

### DETAILED DESCRIPTION OF EXEMPLARY EMBODIMENTS

### Embodiment 1

There provides an optimization method of thickness uniformity of an alignment film which is used to a TFT array substrate, and the optimization method includes:

There provides a TFT array substrate (not shown in the figures) with the passivation layer 100 deposited, and the material of the passivation layer is SiNₓ, as shown in FIG. 5.

A photoresist 200 is coated on the passivation layer 100, as shown in FIG. 6.

A half tone mask exposure and a common mask exposure are respectively performed to different regions of the photoresists. Particularly, as shown in FIG. 7, the TFT array substrate is divided into a first region 91 and a second region 92, an incomplete exposure is performed to a photoresist 200 in the first region 91 by using a half tone mask, and the first region may form an ITO film accordingly; and a complete exposure is performed to the photoresist 200 in the second region 92 by using a common lamp shade, and the second region may form contact holes and an ITO film formed in the contact holes accordingly.

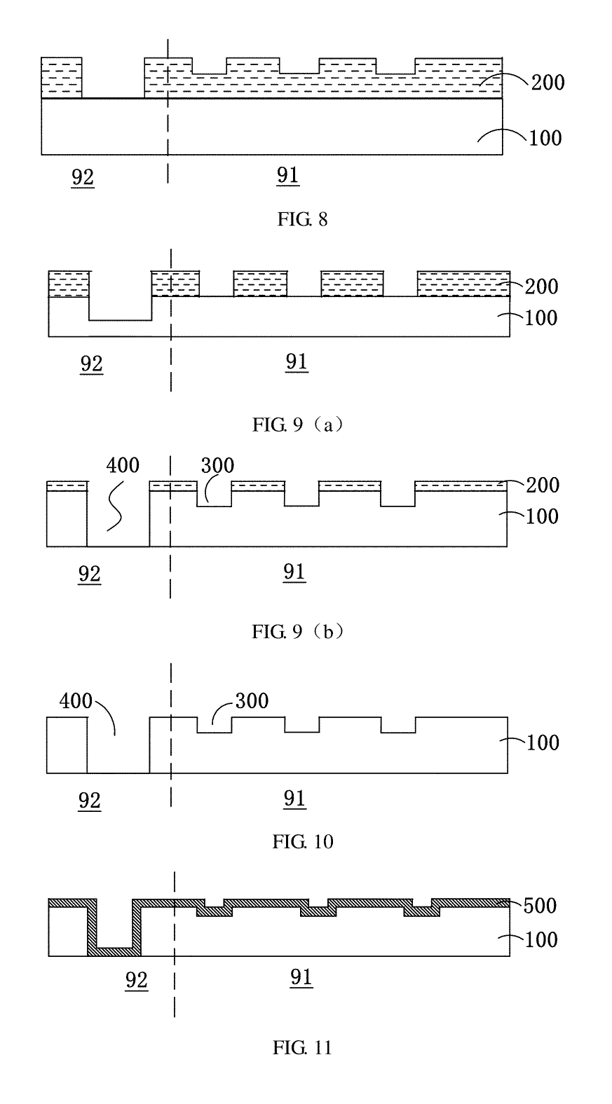

As shown in FIG. 8, a development is performed to the photoresist after being exposed using the half tone mask and the common mask. Particularly, the first region is 91 is developed, since the first region 91 is exposed incompletely, only part of the photoresists in the first region is removed after developing, such that the photoresists in the first region may sink inward to its own body to form several grooves arranged at intervals; and the second region is 92 is developed, since the second region 92 is exposed completely, all of the photoresists in the second region are removed after developing, such that openings passing through the photoresists are formed in the second region.

Next, an etching is performed to the developed photoresist and passivation layer, and the etching course is a continuous process. FIG. 9(a) shows etching states of the photoresists and the passivation layer in course of etching process, and FIG. 9(b) shows structural diagrams of the photoresists and passivation layer after the etching process was completed, thus the changes of the photoresist and the passivation in course of etching process are clearly shown.

In particular, the photoresist 200 in the first region 91 and the passivation layer 100 below the photoresist 200 are etched. First of all, since there are several grooves formed in the photoresists, the photoresists below the groove is thinner than the photoresists at other places. As shown in FIG. 9(a), the thinner photoresists are etched first such that part of the passivation layer in the first region is exposed, and the photoresists at other places are also etched and get thin with the proceeding of the etching process. Then, with the proceeding of the etching, as shown in FIG. 9 (b), the exposed passivation layer may be etched continuously, and the upper surface of the passivation layer may sink inward to its own body due to the etching, so as to form several grooves 300 arranged at intervals, and the photoresists in the first region may be etched continuously and get thinner with the proceeding of the etching process.

Openings passing through the photoresists are formed in the second region after developing such that the passivation layer below the photoresists in the second region 92 is partially exposed, thus the etching to the second region after developing exactly is to etch the passivation layer 100 which is partially exposed in the second region 92, and then to form contact holes 400 passing through the passivation layer 100 after etching. The contact hole may be used to allow the drain to be in contact with the ITO film. Meanwhile, the photoresists in the second region may be etched and get thinner and thinner with the proceeding of the etching process.

As shown in FIG. 10, the photoresists are removed by using organic solution. In fact, an object of the above process is to remove the photoresists, thus not only the organic solution but other common processing treatments in other prior arts can be used as a remover for removing the photoresists, for example, by means of a plasma treatment technique, the photoresist can be removed by ashing.

As shown in FIG. 11, upon removing the photoresist, an ITO film 500 is formed on the passivation layer by deposition, such that an ITO film can be deposited on the upper surface, the grooves and the opening of the passivation layer.

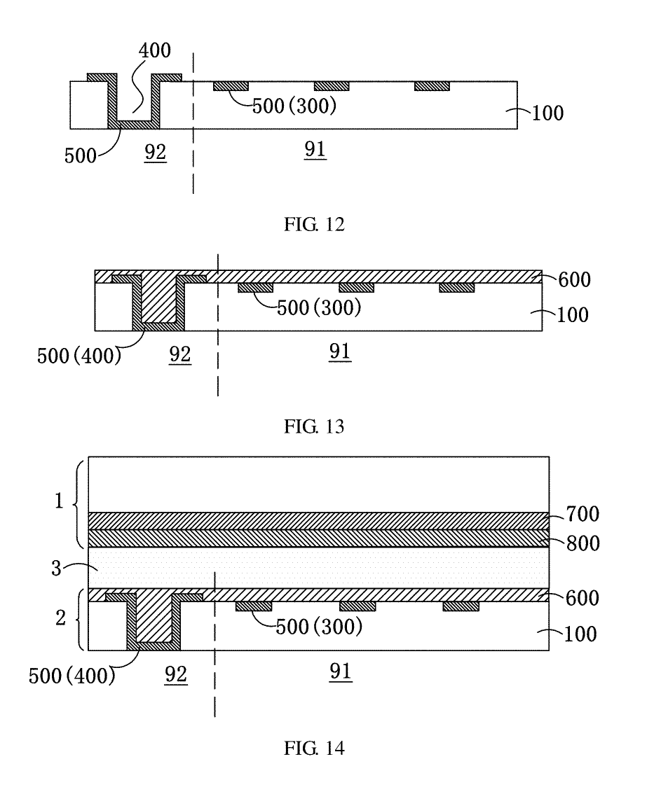

As shown in FIG. 12, to etch the ITO film 500 by using photolithography process, the ITO film on the upper surface of the passivation can be removed, but the ITO film in the groove 300 of the passivation layer may remain, so that the upper surfaces of the passivation layer 100 and the ITO film 500 in the first region 91 are at the same level.

As shown in FIG. 13, an alignment film 600 is coated on the whole surfaces of the etched ITO film 500 and the partially exposed passivation layer 100, and an upper surface of the alignment film 600 is a flat surface. The upper surfaces of the passivation layer and the ITO film in the first region are at the same level, thus when coating the alignment film in the first region, the lower surface of the alignment film is also a flat surface, thus the uniformity of the thickness of the alignment film is guaranteed.

In the present invention, the effect that the upper surfaces of the ITO film and the passivation layer are at the same level can be achieved by employing the half tone mask process, thus when coating the alignment film, a good uniformity of thickness may be achieved, which would not cause a mismatch of thickness of the alignment film due to the mismatch between the ITO film and the passivation layer. Moreover, no extra process steps are added in the optimization method, thus an alignment film having good uniformity of thickness may be obtain without complicating processes.

### Embodiment 2

There provides a liquid crystal display panel manufactured by employing the above optimization method. As shown in FIG. 14, the liquid crystal display panel includes a CF substrate 1 and a TFT array substrate 2 disposed facing to each other, and a liquid crystal layer 3 disposed between the CF substrate and the TFT array substrate.

An ITO film 700 of the CF substrate and an alignment film 800 of the CF substrate are provided on a lower surface of the CF substrate 1. A passivation layer 100 and an ITO film 500 are sequentially disposed on an upper surface of the TFT array substrate 2. The TFT array substrate 2 can be divided into a first region 91 at the right side thereof and a second region 92 at the left side thereof, contact holes 400 passing through the passivation layer are formed in the first region 92, and an ITO film 500 in the second region is deposited on the contact holes 400 to allow the ITO film to be in contact with the drain (not shown).

In the first region 91, there is provided several grooves 300 which are arranged at intervals and sunken inward to the passivation layer 100, the ITO film 500 in the first region is disposed in these grooves 300, and the upper surfaces of the passivation layer and the ITO film 500 in the first region 91 are flat and at the same level. The upper surfaces of the passivation layer 100 and the ITO film 500 in the first region are coated with the alignment film 600 thereon. The upper surface of the alignment film is a flat surface, and the upper surfaces of the ITO film and the passivation layer in the first region are at the same level, thus the lower surface of the alignment film in the first region is also a flat surface.

So, it's understandable that the above explanation is made to the TFT array substrate and the main structure of the liquid crystal display panel, but the TFT array substrate and the liquid crystal display panel can also include other conventional function structures, which are omitted in the present invention.

The above embodiments are detailed embodiments of the present invention, and they are examples enumerated for explaining the present invention clearly, but not limitations to the embodiments of the present invention. To those ordinary skilled in the art, any other change or variation in different forms can also be made based on the above explanation. Here, it cannot or do not have to make an exhaustion to all embodiments. Any amendments, equivalent placement and improvement made within the spirit and principle of the present disclosure should be included in the protection scope of the claims of the present invention.

1. An optimization method of thickness uniformity of alignment film which is used to a liquid crystal display panel, wherein the method comprises:
providing a thin film transistor (TFT) array substrate on which a passivation layer is deposited; coating a photoresist on the passivation layer; dividing the TFT array substrate into different regions, and exposing the photoresist in different regions by respectively using a half tone mask and a common mask; developing the photoresist after being exposed by using the half tone mask and the common mask; etching the developed photoresist and the passivation layer; removing the photoresist after etching; depositing an ITO film after removing the photoresist; etching the ITO film to obtain the TFT array substrate in which upper surfaces of the ITO film and the passivation layer are at a same level; and coating an alignment film on upper surfaces of the ITO film and the passivation layer.

2. The method of claim 1, wherein the TFT array substrate is divided into different regions, and to respectively perform a half tone mask exposure and a common mask exposure to the photoresists in different regions is to divide the TFT array substrate into a first region and a second region, so as to expose the photoresists in the first region by using the half tone mask, and to expose the photoresists in the second region by using the common mask.

3. The method of claim 2, wherein the half tone mask exposure to the photoresists in the first region is an incomplete exposure performed to the photoresists in the first region by using the half tone mask, and an ITO film is formed in the first region accordingly, and the common mask exposure to the photoresist in the second region is a complete exposure performed to the photoresist in the second region by using the common mask, and contact holes are formed in the second region accordingly.

4. The method of claim 3, wherein the photoresist is developed after the half tone mask exposure and the common mask exposure such that the photoresists in the first region form several grooves arranged at intervals and in the second region form openings passing through the photoresists.

5. The method of claim 4, wherein the etching to the developed photoresist and the passivation layer is to etch the photoresists in the first region and the passivation layer below the photoresists such that the passivation layer in the first region forms several grooves arranged at intervals, and to etch the passivation layer in the second region to form contact holes passing through the passivation layer in the second region.

6. The method of claim 2, wherein a TFT array substrate in which the upper surfaces of the ITO film and the passivation layer in the first region are at the same level, is obtained by etching the ITO film.

7. The method of claim 3, wherein a TFT array substrate in which the upper surfaces of the ITO film and the passivation layer in the first region are at the same level, is obtained by etching the ITO film.

8. The method of claim 4, wherein a TFT array substrate in which the upper surfaces of the ITO film and the passivation layer in the first region are at the same level, is obtained by etching the ITO film.

9. The method of claim 6, wherein a lower surface of the alignment film in the first region is a flat surface.

10. The method of claim 1, wherein the deposition of the ITO film after removal of the photoresist is to form the ITO film on the upper surface of the passivation layer by depositing.

11. The method of claim 1, wherein the alignment film is coated on the whole upper surfaces of the ITO film and the passivation layer so that an upper surface of the alignment film is a flat surface.

12. A liquid crystal display panel including a CF substrate and a TFT array substrate disposed facing to each other, and a liquid crystal layer disposed between the CF substrate and the TFT array substrate, wherein a passivation layer and an ITO film is sequentially arranged on an upper surface of the TFT array substrate, and upper surfaces of the passivation layer and the ITO film are at a same level and are coated with an alignment film.
